(19) United States
(12) Patent Application Publication
(10) Pub. No.: US 2014/0028314 A1
(43) Pub. Date: Jan. 30, 2014

(54) METHOD AND APPARATUS FOR ACQUISITION OF MAGNETIC RESONANCE DATA WHILE AVOIDING SIGNAL INHOMOGENEITIES

(71) Applicant: Dominik Paul, Bubenreuth (DE)

(72) Inventor: Dominik Paul, Bubenreuth (DE)

(21) Appl. No.: 13/950,587

(22) Filed: Jul. 25, 2013

(30) Foreign Application Priority Data
Jul. 25, 2012 (DE) 102012213018.7

(51) Int. Cl. G01R 33/387

(52) U.S. Cl. CPC G01R 33/387
USPC 324/309; 324/318

(57) ABSTRACT

In a method and apparatus for the acquisition of magnetic resonance data while avoiding signal inhomogeneities, an excitation pulse is radiated into the examination subject, and following a first time period thereafter, a first refocusing pulse is radiated into the examination subject. After a second time period after the radiation of the first refocusing pulse, a series of at least two additional refocusing pulses is radiated that generate variable flip angles adapted to a predetermined signal curve and that are non-selective pulses. Spin echo signals generated by the radiated pulses are acquired as magnetic resonance data. Gradients are activated for spatial coding. The center frequency of at least one of the radiated refocusing pulses is adjusted such that it is between the resonance frequency of fat molecules and the resonance frequency of water molecules in the examination subject in the magnetic resonance system.

### BACKGROUND OF THE INVENTION

1. Field of the Invention

The present invention concerns a method to acquire magnetic resonance data, as well as a magnetic resonance system and an electronically readable data storage medium for implementing such a method.

2. Description of the Prior Art

Magnetic resonance (MR) is a known modality with which images of the inside of an examination subject can be generated. Expressed in a simplified manner, the examination subject in a magnetic resonance apparatus is positioned in a strong, static, homogeneous basic magnetic field (also called a B₀ field) with a field strength of 0.2 to 7 Tesla or more, such that nuclear spins in the subject orient along the basic magnetic field. Radio-frequency excitation pulses and possible refocusing pulses (RF pulses) are radiated into the examination subject to trigger nuclear magnetic resonance signals, are detected and entered into a memory in an organization as k-space data, on the basis of which MR images are reconstructed or spectroscopy data are determined. Rapidly switched magnetic gradient fields are superimposed on the basic magnetic field for spatial coding of the measurement data. The acquired measurement data are digitized and stored as complex numerical values in a k-space matrix. For example, by means of a multidimensional Fourier transformation an associated MR image can be reconstructed from the k-space matrix populated with values.

In the acquisition of magnetic resonance data from a three-dimensional region of an examination subject, signal inhomogeneities result due to inhomogeneities in the basic magnetic field. Such signal inhomogeneities can lead to a decrease of signals in regions of the acquired MR images that are important to a finding. The diagnostic value of the acquired MR images is thereby reduced. Even in the case of an ideally homogeneous basic magnetic field, the problem continues to exist since fat and water protons exhibit different resonance frequencies due to the chemical shift, and under the circumstances the entire region cannot be covered with the bandwidth of one radio-frequency pulse. The greater the field strength of the basic magnetic field, the further apart from one another the resonance frequencies are separated.

### SUMMARY OF THE INVENTION

An object of the present invention is to provide a method to acquire magnetic resonance data and a magnetic resonance system and an electronically readable data storage medium to implement such a method that already, during the generation of the spin echo signals that are acquired as magnetic resonance data, avoid signal inhomogeneities in image data reconstructed magnetic resonance data, in spite of inhomogeneities in the basic magnetic field and in spite of effects of the chemical shift.

The invention is based on the insight that long RF pulses with reduced bandwidth are the most susceptible to inhomogeneities in the basic magnetic field, with the effect that spectral regions are not excited or refocused, since the bandwidth of an RF pulse is inversely proportional to the duration of the RF pulse.

For example, in magnetic resonance systems with a higher basic magnetic field (for example 3 Tesla or more), the required B1 field is normally realized in a reduced form compared to magnetic resonance systems with a basic magnetic field of a lower strength, so the duration of the RF pulses of a data acquisition sequence is extended and the bandwidth of the RF pulses is reduced. As noted above, such sequences are particularly susceptible to inhomogeneities in the basic magnetic field.

A method according to the invention for the acquisition of magnetic resonance data with a magnetic resonance system in order to avoid signal inhomogeneities includes radiating an excitation pulse into the examination subject, after a first time period after the radiation of the excitation pulse, radiating a first refocusing pulse into the examination subject, after a second time period after the radiation of the first refocusing pulse, radiating a series of at least two additional refocusing pulses that generate variable flip angles adapted to a predetermined signal curve and are non-selective pulses, acquiring the spin echo signals generated by the radiated pulses as magnetic resonance data, activating gradients for spatial coding the excitation produced by the excitation pulse, the refocusing via the refocusing pulses and the acquisition of the magnetic resonance data, and storing and/or further processing the acquired magnetic resonance data, wherein the center frequency of at least one of the radiated refocusing pulses is adjusted such that it is arranged between the resonance frequency of fat molecules and the resonance frequency of water molecules in the examination subject in the magnetic resonance system.

Inhomogeneities in the signal intensity of the acquired magnetic resonance data (and therefore signal inhomogeneities) are avoided with the center frequency, adjusted according to the invention, of at least one of the radiated refocusing pulses of the method according to the invention. The non-selective refocusing pulses excite both fat molecules and water molecules as homogeneously as possible via the adjustment according to the invention.

This applies in principle to every individual radiated refocusing pulse. The selection of at which refocusing pulses an adapted center frequency should be adjusted depends on the type of measurement and the desired influence on the quality of the image data that can be reconstructed from the acquired measurement data. For example, the center frequencies of all radiated refocusing pulses can be shifted according to the invention, although this is not necessary.

In one embodiment, at least the center frequency of the first refocusing pulse is shifted according to the invention to a position between the resonance frequencies of fat and water. Particularly if the first refocusing pulse is a 180° pulse in order to generate a pure spin echo with high signal intensity, this first refocusing pulse is longer than the additional refocusing pulses that normally generate smaller flip angles. For both of these reasons (generation of a pure spin echo and longer duration of the first refocusing pulse relative to the additional refocusing pulses), this first refocusing pulse is most sensitive with regard to the problem addressed above and also has the greatest influence on the quality of the image data that can be reconstructed from the acquired measurement data.

Through the series of at least two refocusing pulses after one excitation pulse, an echo train of similarly many spin echoes is generated. Because the refocusing pulses generate variable flip angles adapted to a predetermined signal curve, particularly long echo trains can be generated via correspondingly many refocusing pulses without the signal intensities of the echoes declining too severely. Appropriate methods to determine and implement the variable flip angles are known from, for example: Mugler, Kiefer and Brookeman: “Three-Dimensional T2-Weighted Imaging of the Brain Using Very Long Spin-Echo Trains”, Proc. ISMRM 8 (2000) P. 687; Mugler, Meyer and Kiefer: “Practical Implementation of Optimized Tissue-Specific Prescribed Signal Evolutions for Improved Turbo-Spin-Echo Imaging”, Proc. ISMRM 11 (2003) P. 203; Mugler and Brookeman: “3D Turbo-Spin-Echo Imaging with up to 1000 Echoes per Excitation: From Faster Acquisitions to Echo-Volumar Imaging”, Proc. ISMRM 11(2004) P. 2106; and Mugler and Brookeman: “Efficient Spatially-Selective Single-Slab 3D Turbo-spin-Echo Imaging”, Proc. ISMRM 11 (2004) P. 695.

In contrast to older sequences, for example a TSE sequence (“Turbo Spin Echo”) or an FSE sequence (“Fast Spin Echo”), the readout module of the pulse sequence according to the invention advantageously corresponds to a SPACE sequence (“Sampling Perfection with Application optimized Contrasts using different flip angle Evolutions”). For example, this SPACE sequence has proven preferable to the older TSE and FSE sequences due to the variable flip angles and the longer echo train lengths that are possible from this sequence, than are normal in practice. SPACE (“Sampling Perfection with Application optimized Contrasts using different flip angle Evolution”) allows high-resolution, three-dimensional (3D) image exposures to be created in a shorter period of time. The SPACE sequence is a single slice 3D turbo spin echo (TSE) sequence with application-specific variable flip angles.

A magnetic resonance system according to the invention for the acquisition of magnetic resonance data in a selected region within an examination subject has a basic field magnet, a gradient field system, at least one RF antenna, and a control device to control the gradient field system and the at least one RF antenna, to receive the measurement signals acquired by the at least one RF antenna, and to evaluate the measurement signals and to create the magnetic resonance data, and a computer to determine the center frequency of the refocusing pulses and to determine flip angles adapted from a predetermined signal curve. The magnetic resonance system is operated by the control unit to radiate an excitation pulse into the examination subject and after the excitation pulse, to radiate a first refocusing pulse into the examination subject after a first time period, with the center frequency of at least one of the radiated refocusing pulses being set by means of the computer so that it is between the resonance frequency of fat molecules and the resonance frequency of water molecules in the examination subject. The control unit further operates the magnetic resonance system; such that, after a second time period, a series of at least two refocusing pulses is radiated in order to generate spin echo signals in the examination subject. The refocusing pulses generate variable flip angles adapted to a predetermined signal curve, and the refocusing pulses of the series of at least two refocusing pulses are non-selective pulses. The control unit operates the magnetic resonance system to acquire the generated spin echo signals as magnetic resonance data and such that the magnetic resonance system activates gradients for spatial coding before and after the radiation of the excitation pulse, the radiation of the refocusing pulses and during the data acquisition. The magnetic resonance system stores and/or displays the acquired magnetic resonance data.

In general, the magnetic resonance system is designed to implement the method according to the invention as described herein.

An electronically readable data medium according to the invention has electronically readable control information stored thereon that cause a computerized control device of a magnetic resonance system to implement the method according to the invention.

The advantages and embodiments specified with regard to the inventive method apply analogously to the magnetic resonance system and the electronically readable data medium.

### BRIEF DESCRIPTION OF THE DRAWINGS

FIG. 1 schematically illustrates a magnetic resonance system according to the invention.

FIG. 2 shows an example of a pulse sequence suitable for use in the method according to the invention.

FIG. 3 schematically shows an adjustment according to the invention of the center frequency of the first refocusing pulse of the pulse sequence that is used.

FIG. 4 is a flowchart of an embodiment of the method according to the invention.

### DESCRIPTION OF THE PREFERRED EMBODIMENTS

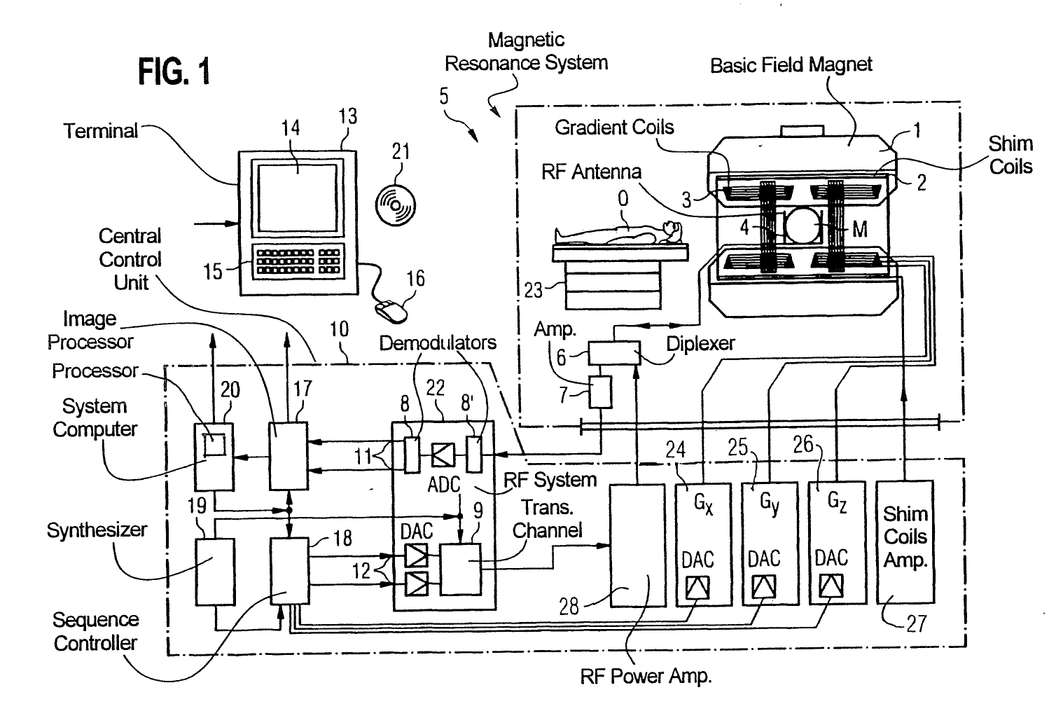

FIG. 1 is a schematic representation of a magnetic resonance system 5 (a magnetic resonance imaging or magnetic resonance tomography apparatus). A basic field magnet 1 generates a temporally constant, strong magnetic field for polarization or alignment of the nuclear spins in a selected region O of an examination subject U, for example of a part of a human body that is to be examined. The body lies on a table 23 and is examined in the magnetic resonance system 5. The high homogeneity of the basic magnetic field that is required for the magnetic resonance measurement (data acquisition) is defined in a typically (but not necessarily) spherical measurement volume M into which the parts of the human body that are to be examined are introduced. Shim plates made of ferromagnetic material are attached at suitable points to assist the homogeneity requirements, and in particular to eliminate temporally invariable influences. Temporally variable influences are eliminated by shim coils 2 operated by a shim coils amplifier 27.

A cylindrical gradient coil system 3 composed of three sub-windings is used in the basic field magnet 1. Each sub-winding is supplied with current by an amplifier to generate, for example, a linear (also temporally variable) gradient field in the respective direction of the Cartesian coordinate system. The first sub-winding of the gradient field system 3 generates a gradient Gₓ in the x-direction; the second sub-winding generates a gradient G_{y} in the y-direction; and the third sub-winding generates a gradient G_{z} in the z-direction. The amplifier comprises a digital/analog converter which is activated by a sequence controller 18 for accurately-timed generation of gradient pulses.

Located within the gradient field system 3 are one (or more) radio-frequency antennas 4—in particular at least one multichannel RF transmission coil and at least one RF reception coil—that convert the radio-frequency pulses emitted by a radio-frequency power amplifier 28 into an alternating magnetic field for excitation of the nuclei and alignment of the nuclear spins of the examination subject U to be examined, or of the region of the selected region O of the examination subject U that is to be examined. Each radio-frequency antenna 4 is composed of one or more RF transmission coils and multiple RF reception coils in the form of an annular—preferably linear or matrix-like—arrangement of component coils. The alternating field emanating from the precessing nuclear spins—i.e. normally the spin echo signals caused by a pulse sequence composed of one or more radio-frequency pulses and one or more gradient pulses—is also converted by the RF reception coils of the respective radio-frequency antenna 4 into a voltage (measurement signal) which is supplied via an amplifier 7 to a radio-frequency reception channel 8 of a radio-frequency system 22. The radio-frequency system 22 furthermore has a transmission channel 9 in which the radio-frequency pulses are generated for the excitation of nuclear magnetic resonance. The respective radio-frequency pulses are digitally represented in the sequence controller 18 as a series of complex numbers based on a pulse sequence predetermined by the system computer 20, which has a computer 24 to determine flip angles adapted to a predetermined signal curve. This number sequence is supplied as a real part and an imaginary part to a digital/analog converter in the radio-frequency system 22 via respective inputs 12, and from said digital/analog converter to the transmission channel 9. In the transmission channel 9, the pulse sequences are modulated on a radio-frequency carrier signal whose base frequency corresponds to the center frequency.

The switching from transmission operation to reception operation takes place via a transmission/reception diplexer 6. The RF transmission coils of the radio-frequency antenna(s) 4 radiate(s) the radio-frequency pulses for excitation of the nuclear spins into the measurement volume M, and resulting echo signals are scanned via the RF reception coil(s). The correspondingly acquired nuclear magnetic resonance signals are phase-sensitively demodulated to an intermediate frequency in a reception channel 8′ (first demodulator) of the radio-frequency system 22 and digitized in an analog/digital converter (ADC). This signal is further demodulated to a frequency of 0. The demodulation to a frequency of 0 and the separation into real part and imaginary part occur in a second demodulator 8 after the digitization in the digital domain. An MR image or three-dimensional image data set can be reconstructed by an image computer 17 from the measurement data acquired in such a manner. The administration of the measurement data, the image data and the control programs takes place via the system computer 20. Based on a specification with control programs, the sequence controller 18 monitors the generation of the respective desired pulse sequences and the corresponding scanning of k-space. In particular, the sequence controller 18 controls the accurately-timed switching of the gradients, the emission of the radio-frequency pulses with defined phase amplitude and the reception of the nuclear magnetic resonance signals.

The time base for the radio-frequency system 22 and the sequence controller 18 is provided by a synthesizer 19. The selection of corresponding control programs to generate an acquisition of magnetic resonance data (which programs are stored on a DVD 21, for example), the selection of a selected region O that should be excited and from which magnetic resonance data should be received, the specification of a substance with which the selected region O is filled to determine the flip angles for the desired signal curve, and the presentation of a generated MR image take place via a terminal 13 (for example) that has a keyboard 15, a mouse 16 and a monitor 14.

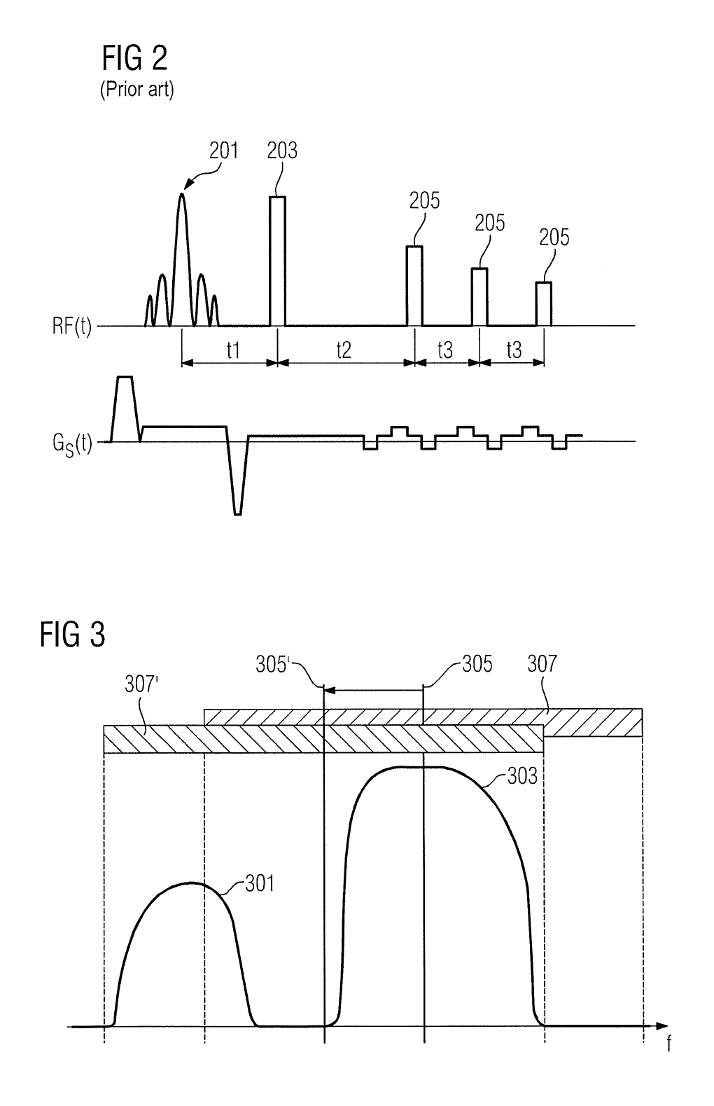

FIG. 2 shows an example of a pulse sequence scheme that can be used for the method according to the invention.

The radio-frequency pulses to be radiated are shown in the upper line (RF(t)). After the excitation pulse 201—for example a 90° pulse (meaning that it generates a flip angle of approximately 90°)—a first refocusing pulse 203 is radiated after a first time period t1. After a second time period t2 after the first refocusing pulse 203, a first additional refocusing pulse 203 (of a series of at least two additional refocusing pulses 205 which have the time interval t3 among one another) is radiated after a second time period t2. For example, the first refocusing pulse 203 is hereby a 180° pulse, meaning that it generates a flip angle of approximately 180°. The additional refocusing pulses 205 generate variable flip angles adapted to a predetermined signal curve and are non-selective pulses.

The signal curve is hereby dependent on a predetermined substance with which the selected region is filled. Through the variably adapted flip angles, a predetermined signal strength for the respective refocusing pulse can be achieved at the readout of the magnetic resonance data generated via the refocusing pulse.

The refocusing pulses 205 generate spin echo signals that are read out in a known manner (not shown).

In the lower line, the gradients (Gz(t)) to be switched before and during the refocusing pulses and the readout are shown as examples.

The pulse sequence that is used can thus in particular be a SPACE sequence as already addressed above.

FIG. 3 schematically shows setting, according to the invention, of the center frequency of the first refocusing pulse of the pulse sequence that is used.

The horizontal axis (f) indicates the frequency. The peak 301 shown to the left corresponds to the resonance frequencies of fat occurring in a magnetic resonance system given an assumed homogenous basic magnetic field and in the examination subject. The additional peak 303 shown to the right corresponds to the resonance frequencies of water occurring in the examination subject in the magnetic resonance system.

In the prior art, the center frequency 203 of an excitation or refocusing pulse is optimally placed centrally in the spectral range 303 of water. The bandwidth 307 of this pulse should optimally cover the entire spectral range 303 of water, and often also the spectral range 301 of fat. The spectral range of all protons to be shown should generally be covered. A broad bandwidth—but, for technical reasons (for example a limited possible B1 field) also a limited bandwidth—is normally selected. As is illustrated by the dotted lines at the ends of the drawn bandwidth 307, frequency ranges which lie outside of the spectral range 303 of water are also excited or refocused by the pulse. In the shown example, a portion of the spectral range 301 of fat is also excited or, respectively, refocused, but not the entire spectral range 301 of fat.

According to the invention, the center frequency 305′ of one of the refocusing pulses radiated given the pulse sequence used is now shifted “to the left”, such that it lies between the spectral range 301 of fat and the spectral range 303 of water. The center frequency 305′ of the affected refocusing pulse is therefore arranged between the possible resonance frequencies of fat molecules and the possible resonance frequencies of water molecules in the examination subject in the magnetic resonance system given an assumed homogenous basic magnetic field. The bandwidth 307′ of the adapted refocusing pulse is thereby selected such that the spectral width of the resonance frequencies of fat molecules is fully covered and, ideally, the refocusing of the water molecules is also not limited, meaning that the spectral width of the resonance frequencies of water molecules are also fully covered. The selected center frequency thereby does not necessarily lie exactly in the middle between the possible resonance frequencies of water molecules in the examination subject in the magnetic resonance system; rather, it is only shifted from the central position in the spectral range 303 of water in the direction of the spectral range 301 of fat. However, in a simple exemplary embodiment that is normally easy to implement, it can also be arranged centrally between the possible resonance frequencies of fat molecules and the possible resonance frequencies of water molecules in the examination subject in the magnetic resonance system.

The spectral ranges 301 and 303 of fat and water are therefore simultaneously covered by the bandwidth 307′ of the refocusing pulse shifted according to the invention, and the affected spins are thus refocused. Spins with resonance frequencies that are possibly shifted due to inhomogeneities of the basic magnetic field of the magnetic resonance apparatus are thereby still refocused, whereby these can also contribute to the signal intensity. Signal inhomogeneities are thus effectively avoided.

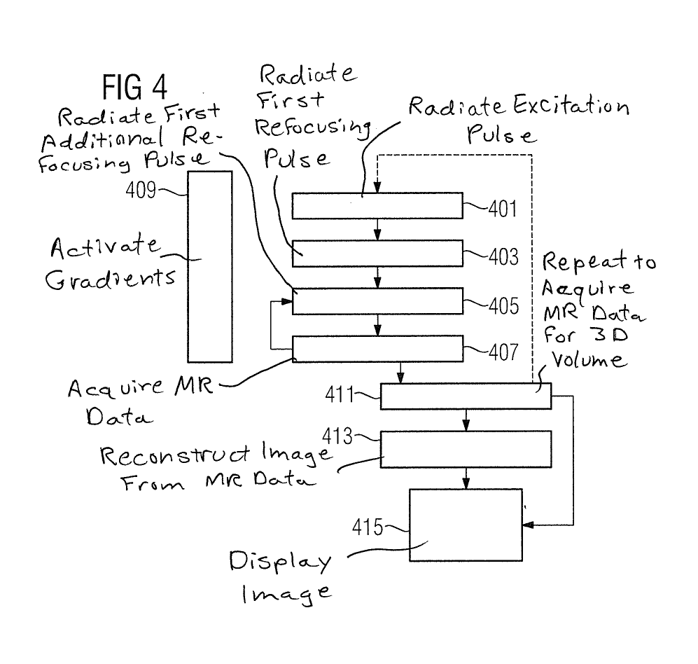

FIG. 4 is a schematic workflow diagram of a method according to the invention to acquire magnetic resonance data by means of a magnetic resonance system to avoid signal inhomogeneities.

An excitation pulse is initially radiated into the examination subject, which excites the nuclear spins in said examination subject (Block 401).

After a first time period after the radiation of the excitation pulse, a first refocusing pulse is radiated into the examination subject (Block 403).

After a second time period after the radiation of the first refocusing pulse, a first additional refocusing pulse is initially radiated (Block 405) which generates a spin echo that is acquired as magnetic resonance data (Block 407). This process (Blocks 405 and 407) is run through at least twice, or is repeated until a series of a desired number of refocusing pulses (but at least two additional refocusing pulses) has been radiated. The refocusing pulses that are radiated generate variable flip angles adapted to a predetermined signal curve and are non-selective pulses.

The center frequency of at least one of the radiated refocusing pulses (Blocks 403 and 405) is thereby adjusted (as with regard to FIG. 3) such that it lies between the resonance frequency of fat molecules and the resonance frequency of water molecules arranged in the examination subject in the magnetic resonance system.

Given the excitation by the excitation pulse, the refocusing via the refocusing pulses and the acquisition of the magnetic resonance data, gradients for spatial coding are switched in a known manner (Block 409).

The acquired magnetic resonance data are stored for further processing and/or for a display (Block 411). For example, image data can be reconstructed from the acquired magnetic resonance data (Block 413). Furthermore, the acquired magnetic resonance data and/or the image data reconstructed from the acquired magnetic resonance data can be displayed at a suitable display device, for example a monitor (Block 415).

In one embodiment of the method, the enumerated steps of the method—in particular Steps 401 through 411 (radiate an excitation pulse, radiate a first and additional refocusing pulses, acquire magnetic resonance data and store and/or further process the acquired magnetic resonance data) are repeated while activating different gradients in Block 409 until magnetic resonance data have been acquired from a desired three-dimensional volume of the examination subject. A region that is larger overall—for example a three-dimensional region—can therefore also be covered via selection of different adjacent slices. This is indicated by the dashed arrow from Block 411 back to Block 401 in FIG. 4.

In the exemplary embodiment of the method, magnetic resonance data are generated and acquired from the region of the cervical spinal column of the examination subject. Inhomogeneities of the basic magnetic field often occur in the region of the cervical spinal column, for example due to susceptibility effects. However, such susceptibility effects have less of an effect on magnetic resonance data acquired with the method according to the invention, so the image quality is improved.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for acquiring magnetic resonance data, comprising:
operating a magnetic resonance data acquisition unit, in which an examination is located, to radiate an excitation pulse into the examination subject that excites nuclear spins in the examination subject;
operating said magnetic resonance data acquisition unit to radiate, after a first time period following radiation of said excitation pulse, a first refocusing pulse into the examination subject;
operating said magnetic resonance data acquisition unit to radiate, following a second time period after radiating said first refocusing pulse, a series of at least two additional refocusing pulses that generate variable flip angles of the nuclear spins that are adapted to a predetermined signal curve, with each of said at least two additional refocusing pulses being a non-selective pulse;
adjusting a center frequency of at least one of said refocusing pulses to place said center frequency between a resonance frequency of fat molecules in the examination subject and a resonance frequency of water molecules in the examination subject;
operating said magnetic resonance data acquisition unit to acquire spin echo signals produced by the excited nuclear spins, as magnetic resonance data;
operating the data acquisition unit to activate gradients that spatially encode excitation of the nuclear spins by the excitation pulse and the refocusing produced by the refocusing pulses, and the acquired magnetic resonance data; and
providing said acquired magnetic resonance data to a processor, and making the acquired magnetic resonance data, or an image reconstructed therefrom, available at an output of the processor in electronic form as a data file.

2. A method as claimed in claim 1 comprising operating said data acquisition unit to set the center frequency of the first refocusing pulse to be between the resonance frequency of fat molecules in the examination subject and the resonance frequency of water molecules in the examination subject.

3. A method as claimed in claim 1 comprising radiating said first refocusing pulse with a bandwidth that completely covers a spectral width of resonant frequencies of said fat molecules in the examination subject.

4. A method as claimed in claim 1 comprising radiating said first refocusing pulse with a bandwidth that completely covers a spectral width of resonant frequencies of said water molecules in the examination subject.

5. A method as claimed in claim 1 repeating radiation of said excitation pulse, radiation of said first refocusing pulse, radiation of said series of at least two additional refocusing pulses, acquisition of said spin echo signals and activation of said gradients multiple times until MR data from a predetermined three-dimensional volume of the examination subject are acquired.

6. A method as claimed in claim 1 comprising operating said magnetic resonance data acquisition unit to radiate said first refocusing pulse as a 180° pulse.

7. A method as claimed in claim 1 comprising operating said magnetic data acquisition unit to acquire said MR data from a region of the cervical spinal column of the examination subject.

8. A method as claimed in claim 1 comprising setting the center frequency of at least the first refocusing pulse to be centrally located between said resonance frequency of fat molecules in the examination subject and said resonance frequency of water molecules in the examination subject.

9. A magnetic resonance system comprising:
a magnetic resonance data acquisition unit adapted to receive an examination subject therein;
a control unit configured to operate the magnetic resonance data acquisition unit to radiate an excitation pulse into the examination subject that excites nuclear spins in the examination subject;
said control unit being configured to operate said magnetic resonance data acquisition unit to radiate, after a first time period following radiation of said excitation pulse, a first refocusing pulse into the examination subject;
said control unit being configured to operate said magnetic resonance data acquisition unit to radiate, following a second time period after radiating said first refocusing pulse, a series of at least two additional refocusing pulses that generate variable flip angles of the nuclear spins that are adapted to a predetermined signal curve, with each of said at least two additional refocusing pulses being a non-selective pulse;
said control unit being configured to adjust a center frequency of at least one of said refocusing pulses to place said center frequency between a resonance frequency of fat molecules in the examination subject and a resonance frequency of water molecules in the examination subject;
said control unit being configured to operate said magnetic resonance data acquisition unit to acquire spin echo signals produced by the excited nuclear spins, as magnetic resonance data;
said control unit being configured to operate the data acquisition unit to activate gradients that spatially encode excitation of the nuclear spins by the excitation pulse and the refocusing produced by the refocusing pulses, and the acquired magnetic resonance data; and
a processor provided with said acquired magnetic resonance data configured to make the acquired magnetic resonance data, or an image reconstructed therefrom, available at an output of the processor in electronic form as a data file.

10. A non-transitory, computer-readable data storage medium encoded with programming instructions, said storage medium being loaded into a computerized control and evaluation system of a magnetic resonance apparatus, said magnetic resonance apparatus also comprising a magnetic resonance data acquisition unit, said programming instructions causing said control and evaluation system to:
operate the magnetic resonance data acquisition unit, in which an examination is located, to radiate an excitation pulse into the examination subject that excites nuclear spins in the examination subject;
operate said magnetic resonance data acquisition unit to radiate, after a first time period following radiation of said excitation pulse, a first refocusing pulse into the examination subject;
operate said magnetic resonance data acquisition unit to radiate, following a second time period after radiating said first refocusing pulse, a series of at least two additional refocusing pulses that generate variable flip angles of the nuclear spins that are adapted to a predetermined signal curve, with each of said at least two additional refocusing pulses being a non-selective pulse;
adjust a center frequency of at least one of said refocusing pulses to place said center frequency between a resonance frequency of fat molecules in the examination subject and a resonance frequency of water molecules in the examination subject;
operate said magnetic resonance data acquisition unit to acquire spin echo signals produced by the excited nuclear spins, as magnetic resonance data;
operate the data acquisition unit to activate gradients that spatially encode excitation of the nuclear spins by the excitation pulse and the refocusing produced by the refocusing pulses, and the acquired magnetic resonance data; and
make the acquired magnetic resonance data, or an image reconstructed therefrom, available at an output of the control and evaluation system in electronic form as a data file.
